(19) United States
(12) Patent Application Publication
(10) Pub. No.: US 2025/0393330 A1
(43) Pub. Date: Dec. 25, 2025

(54) IMAGE SENSOR

(71) Applicant: Samsung Electronics Co., Ltd., Suwon-si (KR)

(72) Inventors: YOUNGWOO CHUNG, Suwon-si (KR); JEONGKI KIM, Suwon-si (KR); HYOUNMIN BAEK, Suwon-si (KR); KYOUNGMOK SON, Suwon-si (KR); DONGWOON LEE, Suwon-si (KR); WONYOUNG LEE, Suwon-si (KR)

(21) Appl. No.: 19/028,475

(22) Filed: Jan. 17, 2025

(30) Foreign Application Priority Data
Jun. 25, 2024 (KR) 10-2024-0082917

(51) Int. Cl. H10F 39/00

(52) U.S. Cl. CPC H10F 39/811

(57) ABSTRACT

An image sensor includes a substrate having first and second surfaces facing away from each other, the substrate including a pixel region and a dummy region, a photoelectric conversion portion provided in the pixel region of the substrate, and a wiring layer on the first surface. The wiring layer includes a plurality of insulating layers, a discharge line, and a discharge contact. The discharge line extends from the pixel region to the dummy region in one or more of the plurality of insulating layers. The discharge contact is in contact with the first surface on the dummy region.

### CROSS-REFERENCE TO RELATED APPLICATIONS

This U.S. non-provisional patent application claims priority under 35 U.S.C. § 119 to Korean Patent Application No.10-2024-0082917 filed on Jun. 25, 2024, in the Korean Intellectual Property Office, the entire contents of which are hereby incorporated by reference.

### BACKGROUND OF THE INVENTION

The inventive concept relates to an image sensor, and more specifically, relates to an image sensor having improved electrical and optical characteristics.

Image sensors are semiconductor devices that convert an optical image into an electrical signal. The image sensors may be classified into charge coupled device (CCD) type image sensors and a complementary metal oxide semiconductor (CMOS) type image sensors. The CIS is short for the CMOS type image sensor. The CIS includes two-dimensionally disposed pixels. Each of the pixels includes a photodiode (PD). The photodiode converts incident light into an electrical signal.

### SUMMARY

An object of the inventive concept is to provide an image sensor with improved process defects and improved optical characteristics.

The problem to be solved by the inventive concept is not limited to the problems mentioned above, and other problems not mentioned will be clearly understood by those skilled in the art from the description below.

An image sensor according to some embodiments of the inventive concept may include a substrate having first and second surfaces facing away from each other, the substrate including a pixel region and a dummy region, a photoelectric conversion portion provided in the pixel region of the substrate, and a wiring layer on the first surface, wherein the wiring layer includes a plurality of insulating layers, a discharge line, and a discharge contact, the discharge line extends from the pixel region to the dummy region in one or more of the plurality of insulating layers, and the discharge contact is in contact with the first surface on the dummy region.

An image sensor according to some embodiments of the inventive concept may include a substrate including a pixel region and a dummy region, a photoelectric conversion portion provided in the pixel region of the substrate, and a discharge line and a discharge contact on the substrate, wherein the discharge contact is provided on the discharge line, when viewed in a plan view, the dummy region surrounds the pixel region, the discharge line overlaps the pixel region and the dummy region, and the discharge contact overlaps the dummy region.

An image sensor according to some embodiments of the inventive concept may include a substrate including a pixel region, a dummy region, and a pad region, and having first and second surfaces facing away from each other, a photoelectric conversion portion provided in the pixel region of the substrate, pixel separation portions disposed in the pixel region and the dummy region in the substrate, and a wiring layer on the first surface of the substrate, wherein the wiring layer includes an interlayer insulating layer and a discharge line, wiring patterns, and a discharge contact in the interlayer insulating layer, the discharge line extends from the pixel region to the dummy region, the wiring patterns and the discharge contact are provided on the dummy region, the wiring patterns are disposed between the discharge line and the discharge contact, the discharge contact is in contact with the first surface of the substrate, and the discharge line, the wiring patterns, and the discharge contact are electrically connected to each other.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of an image sensor according to some embodiments of the inventive concept.

FIG. 2 is a cross-sectional view taken along line I-I′ of FIG. 1.

FIG. 3 is an enlarged view of portion ‘CU1’ of FIG. 2.

FIG. 4 is a plan view of an image sensor according to some embodiments of the inventive concept.

FIG. 5 is a cross-sectional view taken along line II-II′ of FIG. 4.

FIGS. 6A, 6B, 6C, and 6D are cross-sectional views illustrating a manufacturing process of an image sensor according to some embodiments of the inventive concept.

FIG. 7 is a plan view illustrating a portion of an image sensor to explain a connection structure and a discharge contact according to some embodiments of the inventive concept.

FIG. 8 is a cross-sectional view of an image sensor according to some embodiments of the inventive concept.

FIG. 9 is an enlarged view of portion ‘CU2’ of FIG. 8.

### DETAILED DESCRIPTION

Hereinafter, the inventive concept will be described in detail by describing embodiments of the inventive concept with reference to the attached drawings.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal, charge, or current can be transferred from one component to the other (although an electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes. Components described as not being electrically connected may be insulated from each other such that an electrical signal, charge, or current does not flow between them.

The term “buried” may refer to structures, patterns, and/or layers that are formed at least partially below a top surface of another structure, pattern, and/or layer. In some embodiments, when a first structure, pattern, and/or layer is “buried” in a second structure, pattern, and/or layer, the second structure, pattern, and/or layer may surround at least a portion of the first structure, pattern, and/or layer. For example, a first structure, pattern, and/or layer first may be considered to be buried when it is at least partially embedded in a second structure, pattern, and/or layer.

The term “substrate” may denote a base substrate (e.g., an initial semiconductor substrate forming the base of the wafer in the final wafer product, such as a bulk semiconductor substrate (e.g., formed of crystalline silicon), an silicon on insulator (SOI) substrate, etc.), or a stack structure including such a base substrate and layers formed on the substrate.

A pixel, or unit pixel refers to a sensor element of an image sensor, and may refer to a smallest addressable light-sensing element of the image sensor.

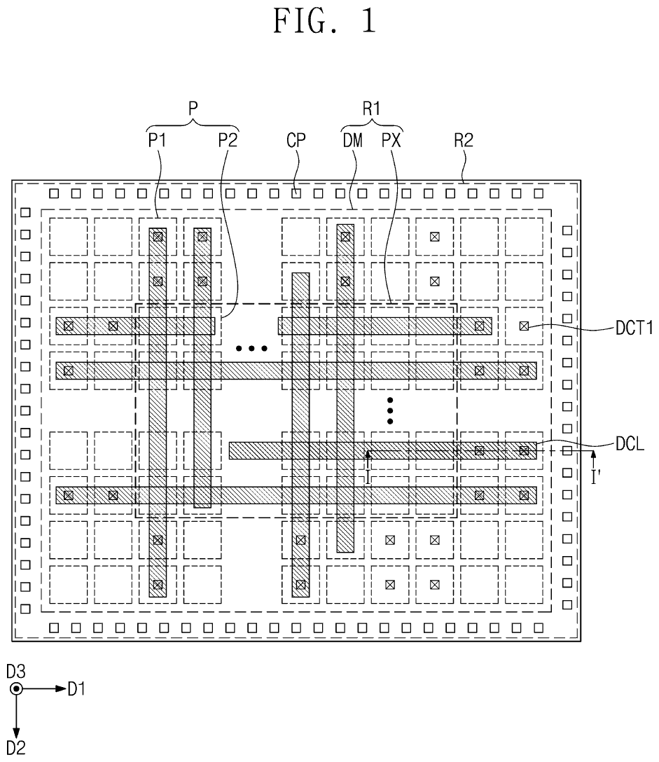

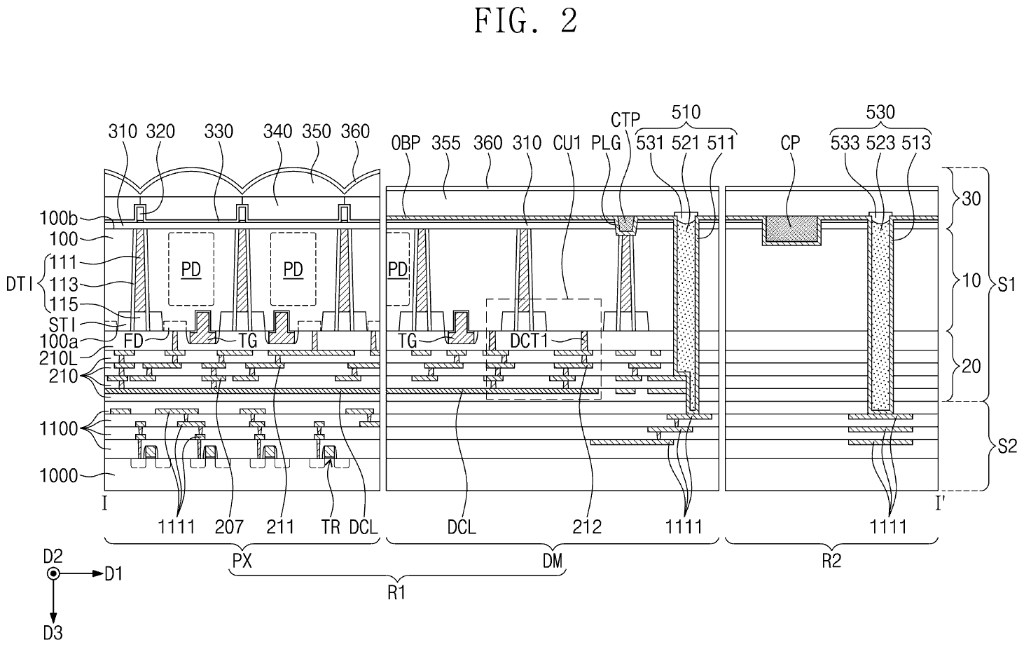

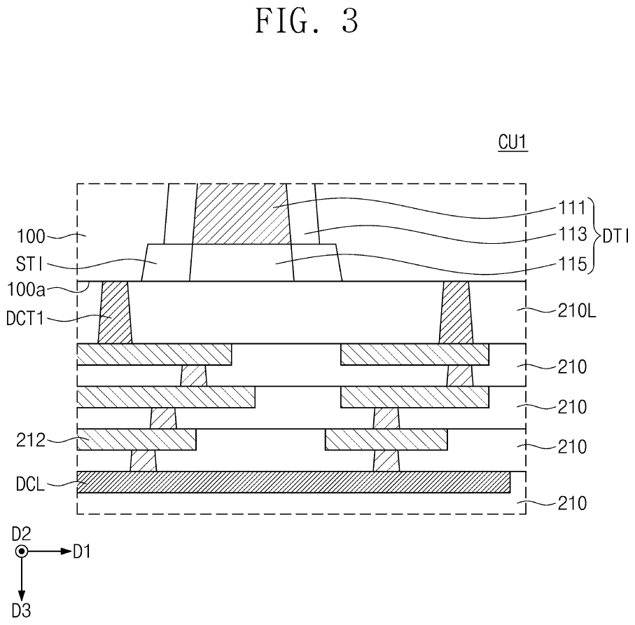

FIG. 1 is a plan view of an image sensor according to some embodiments of the inventive concept. FIG. 2 is a cross-sectional view taken along line I-I′ of FIG. 1. FIG. 3 is an enlarged view of portion ‘CU1’ of FIG. 2.

Referring to FIGS. 1, 2, and 3, an image sensor according to an embodiment of the inventive concept may include a first chip S1 and a second chip S2. The first chip S1 may be a sensor chip. The second chip S2 may be a logic chip. The first chip S1 may, for example, perform an image sensing function. The second chip S2 may include, for example, circuits for driving the first chip S1 or storing an electrical signal generated from the first chip S1.

The first chip S1 may include a substrate 100. The substrate 100 may include a first surface 100a and a second surface 100b that face away from each other. Light may be incident into the substrate 100 through the second surface 100b. The substrate 100 may be a single crystal wafer or an epitaxial layer or a silicon on insulator (SOI) substrate including silicon and/or germanium.

In this specification, a first direction D1 is defined as a direction parallel to the first surface 100a of the substrate 100. The second direction D2 is defined as a direction parallel to the first surface 100a of the substrate 100 and perpendicular to the first direction D1. The third direction D3 is defined as a direction perpendicular to the first surface 100a of the substrate 100. Directions in a plane parallel to the first surface 100a (e.g., defined by the first and second directions D1 and D2) may be referred to as horizontal directions, while the direction perpendicular to the first surface 100a (e.g., the third direction D3) may be referred to as a vertical direction.

The first chip S1 may include a pixel array region R1 and a pad region R2. The pixel array region R1 may include a plurality of pixels P that are two-dimensionally disposed in the first direction D1 and the second direction D2. For example, as shown in FIG. 1, pixels P may include reference pixels P1 within the dummy region DM of pixel array region R1, and unit pixels P2 within the pixel region PX of pixel array region R1. In this specification, a pixel region PX may also be referred to as photoelectric conversion portion region. Each of the unit pixels P2 may include a photoelectric conversion element and a readout element. An electrical signal generated by incident light may be output from each of the unit pixels P2 of the pixel array region R1.

The pixel array region R1 may include a pixel region PX and a dummy region DM. When viewed in a plan view, the dummy region DM may surround the pixel region PX, as illustrated in FIG. 1. In the dummy region DM, reference pixels P1 on which no light is incident may be provided, and the amount of charge sensed by unit pixels P2 of the pixel region PX may be compared with the amount of reference charge generated in the reference pixels P1, thereby calculating the size of the electrical signal detected in the unit pixels P2.

A plurality of conductive pads CP used to input/output control signals and photoelectric signals, etc. may be disposed in the pad region R2. When viewed in a plan view, the pad region R2 may surround the pixel array region R1. The conductive pads CP may input/output the electrical signals generated in the unit pixels P2 to an external device.

Referring again to FIG. 2, the image sensor according to embodiments of the inventive concept may include a photoelectric conversion layer 10, a wiring layer 20, and a light transmission layer 30 in a vertical view. The photoelectric conversion layer 10 may be disposed between the wiring layer 20 and the light transmission layer 30. Light incident from the outside may be converted into an electrical signal in the photoelectric conversion layer 10. The photoelectric conversion layer 10 may include a substrate 100 and a pixel separation portion (e.g., pixel separation structure) DTI and photoelectric conversion portions (e.g., photoelectric conversion regions) PD disposed inside the substrate 100.

The substrate 100 may be doped with a first impurity to have a first conductivity type. The first impurity may be, for example, boron. The first conductivity type may be, for example, P type.

The pixel separation portion DTI that separates the pixels P from each other may be disposed in the substrate 100. The pixel separation portion DTI may penetrate the substrate 100. The pixel separation portion DTI may have a width that narrows from the first surface 100a to the second surface 100b. The pixel separation portion DTI may be a deep trench isolation layer or structure, and for each pixel P, may be a continuous structure surrounding four sides of the pixel.

The pixel separation portion DTI may include a separation conductive pattern 111, a separation insulating pattern 113, and a buried insulating pattern 115. The separation conductive pattern 111 may be disposed to be spaced apart from the substrate 100. The separation conductive pattern 111 may include a conductive material having a different refractive index from the substrate 100. The separation conductive pattern 111 may include, for example, polysilicon or a metal doped with impurities. The separation insulating pattern 113 may be interposed between the separation conductive pattern 111 and the substrate 100. The buried insulating pattern 115 may be disposed under the separation conductive pattern 111. The separation insulating pattern 113 and the buried insulating pattern 115 may include an insulating material having a different refractive index from the substrate 100. For example, each of the above-described separation insulating pattern 113 and the buried insulating pattern 115 may include silicon oxide.

A negative bias voltage may be applied to the above-described separation conductive pattern 111. The above-described separation conductive pattern 111 may serve as a common bias line. As a result, holes that may exist on a surface of the substrate 100 in contact with the pixel separation portion DTI may be captured, thereby improving dark current characteristics.

A device isolation portion (e.g., device isolation structure) STI may be disposed on the first surface 100a of the substrate 100. The pixel separation portion DTI may be disposed to penetrate a portion of the device isolation portion STI. The device isolation portion STI may include at least one of silicon oxide, silicon nitride, and silicon oxynitride. The device isolation portion STI may be a shallow trench isolation layer or structure, and for each pixel P, may be a continuous structure surrounding four sides of the pixel.

The photoelectric conversion portion PD may be disposed in the substrate 100. In the case of the dummy region DM, there may be a region where the photoelectric conversion portion PD is not disposed. The photoelectric conversion portion PD may be doped with a second impurity and may have a second conductivity type different from the first conductivity type. The second impurity may be, for example, phosphorus or arsenic. The second conductivity type may be, for example, N-type.

A transfer gate electrode TG may be disposed on the first surface 100a of the substrate 100. A portion of the transfer gate electrode TG may penetrate the substrate 100. Although not illustrated, in addition to the transfer gate electrode TG, reset gate electrodes, selection gate electrodes, and source follower gate electrodes may be disposed on the first surface 100a.

A floating diffusion region FD may be disposed adjacent to the transfer gate electrode TG in the pixel region PX of the substrate 100. The floating diffusion region FD may be doped with a second impurity to have a second conductivity type (e.g., the same conductivity type as the photoelectric conversion portion PD).

In this case, the N-type region of the above-described photoelectric conversion portion PD may form a PN junction with the P-type region of the surrounding substrate 100 so as to form a photodiode. When light is incident, electron-hole pairs may be generated by the PN junction, and the electrons generated by the process may move to the photoelectric conversion portion PD.

The wiring layer 20 may be disposed on the first surface 100a of the substrate 100. The wiring layer 20 may include a plurality of interlayer insulating layers 210 and 210L, first wiring patterns 211, second wiring patterns 207, and a discharge line DCL in the pixel region PX.

In detail, a plurality of interlayer insulating layers 210 may be provided on the first surface 100a of the substrate 100. In this case, among the interlayer insulating layers 210, an interlayer insulating layer 210L that is in contact with the first surface 100a may also be referred to as an upper interlayer insulating layer 210L. The interlayer insulating layers 210 and 210L may include at least one of silicon oxide and silicon nitride.

The first wiring patterns 211, the second wiring patterns 207, and the discharge lines DCL may be provided in interlayer insulating layers 210. The first wiring patterns 211, second wiring patterns 207, and discharge lines DCL may be formed of a conductive material such as a metal (e.g., aluminum, copper, silver, gold, tungsten, titanium, tantalum, another metal, or an alloy thereof). The first wiring patterns 211 may be electrically connected to the substrate 100 of the pixel region PX. For example, the first wiring patterns 211 may be electrically connected to the floating diffusion region FD and the photoelectric conversion portion PD. The second wiring patterns 207 may not be electrically connected to the substrate 100 on the pixel region PX. The second wiring patterns 207 may, separately from the first wiring patterns 211, play a role in preventing noise and coupling generated in the pixel region PX when the image sensor operates.

The discharge line DCL may be connected to the second wiring patterns 207. The discharge line DCL may not be electrically connected to the substrate 100 in the pixel region PX. For example, the discharge line DCL may not be electrically connected to the floating diffusion region FD and the photoelectric conversion portion PD in the pixel region PX.

In the dummy region DM, the wiring layer 20 may include a plurality of interlayer insulating layers 210 and 210L, third wiring patterns 212, a discharge line DCL, and first discharge contacts DCT1. The third wiring patterns 212, the discharge line DCL, and the first discharge contacts DCT1 may be provided in the interlayer insulating layers 210. In various examples, the discharge lines DCL and/or first, second, and third discharge contacts DCT1, DCT2, and DCT3, respectively, may be formed of a conductive material such as a metal (e.g., aluminum, copper, silver, gold, tungsten, titanium, tantalum, another metal, or an alloy thereof).

In detail, as shown in FIG. 1, the discharge line DCL may be provided by extending from the pixel region PX to the dummy region DM. The discharge line DCL may extend horizontally, e.g. in the first direction D1 and/or the second direction D2. When viewed in a plan view as in FIG. 1, the discharge line DCL may overlap the pixel region PX and the dummy region DM of the substrate 100. In an example, the discharge line DCL may be continuously formed, for example at a single vertical height (e.g., single level in the third direction D3), between the pixel region PX and the dummy region DM. Alternatively or additionally, the discharge line DCL may be horizontally disposed at different vertical heights in pixel region PX and dummy region DM, and may be connected through one or more connection structures. The discharge line DCL may be provided in the plural (e.g., a plurality of discharge lines DCL may be provided) in the first direction D1 and/or the second direction D2.

In the dummy region DM, the third wiring patterns 212 may be provided on the discharge line DCL. The third wiring patterns 212 may be electrically connected to the discharge line DCL. The third wiring patterns 212 may not be electrically connected to the substrate 100 on the pixel region PX. The third wiring patterns 212 may overlap the dummy region DM.

The first discharge contacts DCT1 may be disposed on the third wiring patterns 212. For example, the third wiring patterns 212 may be interposed between the discharge line DCL and the first discharge contacts DCT1 to connect the discharge line DCL and the first discharge contacts DCT1. The first discharge contacts DCT1, the third wiring patterns 212 and the discharge line DCL may be electrically connected to each other. As shown in FIG. 1, the first discharge contacts DCT1 may be disposed outside the pixel region PX when viewed in a plan view. The first discharge contacts DCT1 may be provided in the plural (e.g., a plurality of first discharge contacts DCT1 may be provided) in the first direction D1 and/or the second direction D2. For example, the discharge contacts DCT1 may be provided in the plural in a direction in which the discharge line DCL extends.

The first discharge contacts DCT1 may penetrate the upper interlayer insulating layer 210L and come into contact with the first surface 100a of the substrate 100. In this case, the first discharge contact DCT1 may be disposed between the device isolation portions STI in the upper insulating layer 210L. The first discharge contact DCT1 may be disposed to be spaced apart from the transfer gate electrode TG in the first direction D1. A width of the first discharge contact DCT1 may decrease (e.g., taper) as the first discharge contact DCT1 approaches the first surface 100a, as shown in FIG. 3.

The light transmission layer 30 may be disposed on the second surface 100b of the substrate 100. The light transmission layer 30 may include a fixed charge layer 310, a grid 320, a protective layer 330, color filters 340, micro lenses 350, and a passivation layer 360 in the pixel region PX. The light transmission layer 30 may collect and filter light incident from the outside and provide the light to the photoelectric conversion layer 10.

The fixed charge layer 310 may be in contact with the second surface 100b of the substrate 100. The fixed charge layer 310 may be formed of a metal oxide layer or a metal fluoride layer containing an amount of oxygen or fluorine less than the stoichiometric ratio. As a result, the fixed charge layer 310 may have a negative fixed charge. For example, the fixed charge layer 310 may be formed of a metal oxide or metal fluoride including at least one metal selected from the group consisting of hafnium (Hf), zirconium (Zr), aluminum (Al), tantalum (Ta), titanium (Ti), yttrium, and lanthanide. Hole accumulation may occur around the fixed charge layer 310. This may effectively reduce occurrence of dark current and white spots. Preferably, the fixed charge layer 310 may include at least one of aluminum oxide and hafnium oxide.

The grid 320 may be disposed on the fixed charge layer 310. The grid 320 may include an optical block pattern and/or a low-refractive pattern. The optical block pattern may include a metal material such as titanium, tantalum, or tungsten, for example. The low-refractive pattern may be formed of a material having a lower refractive index than the optical block pattern. The low-refractive pattern may be formed of an organic material and may have a refractive index of about 1.1 to 1.3.

The protective layer 330 may cover the fixed charge layer 310 and the grid 320. The protective layer 330 may include at least one of an aluminum oxide layer and a silicon oxide.

The color filters 340 may be disposed on the protective layer 330 corresponding to each of the pixel regions PX on the pixel region PX. The color filters 340 may include a red, green, or blue color filter, or a magenta, cyan, or yellow color filter depending on the unit pixel. The color filters 340 may include, for example, a photoresist material to which a dye or pigment is added.

The micro lenses 350 may be disposed on the color filters 340. The micro lenses 350 may have a convex shape and may have a certain radius of curvature. The micro lenses 350 may include a light-transmitting resin.

The passivation layer 360 may be disposed on the micro lenses 350 and may conformally cover surfaces of the micro lenses 350. The passivation layer 360 may include, for example, an inorganic oxide.

The light transmission layer 30 may include an optical block pattern OBP, a backside contact plug PLG, a contact pattern CTP, an organic layer 355, and a passivation layer 360 in the dummy region DM. Some of the pixel separation portions DTI may be connected to the backside contact plug PLG in the dummy region DM.

The backside contact plug PLG may include a metal and/or a metal nitride. For example, the backside contact plug PLG may include titanium and/or titanium nitride. The contact pattern CTP may be embedded in a contact hole in which the backside contact plug PLG is formed. The contact pattern CTP may include a different material from the backside contact plug PLG. The contact pattern CTP may include aluminum (Al), for example.

In the dummy region DM, the optical block pattern OBP may extend continuously from the backside contact plug PLG and be disposed on an upper surface of the fixed charge layer 310. For example, the optical block pattern OBP may include the same material as the backside contact plug PLG. The optical block pattern OBP may block light from being incident on the substrate 100 on the dummy region DM, so as to provide reference pixels P1 on which no light, or a reduced amount of light, is incident. The optical block pattern OBP may include a metal and/or a metal nitride. For example, the optical block pattern OBP may include titanium and/or titanium nitride. The optical block pattern OBP may not extend to the pixel region PX. In the dummy region DM, the organic layer 355 and the passivation layer 360 may be provided on the optical block pattern OBP.

In the dummy region DM, a first connection structure 510 may be provided. The first connection structure 510 may be spaced apart from the discharge line DCL in the first direction D1. For example, as shown in FIG. 2, the first connection structure 510 may extend in the third direction D3, and the discharge line DCL may extend horizontally in the first direction D1 and be spaced apart from the first connection structure 510 in the first direction D1. The first connection structure 510 may include a first through-conductive pattern (e.g., first through-hole conductive pattern) 511, a first buried (e.g., embedded) pattern 521, and a first capping pattern 531. The first through-conductive pattern 511 may penetrate the substrate 100 and be electrically connected to metal wirings of the wiring layer 20 and a wiring structure 1111 of the second chip S2 to be described later. The first through-conductive pattern 511 may have bottom surfaces positioned at different levels. The first buried pattern 521 may be provided inside the first through-conductive pattern 511. The first through-conductive pattern 511 may include, for example, titanium or tungsten. The first embedded pattern 521 may include a low-refractive material and may have insulating properties. The first capping pattern 531 may be provided on the first embedded pattern 521.

In the pad region R2, the conductive pads CP and a second connection structure 530 may be provided on the substrate 100. The conductive pads CP may be embedded in the substrate 100. For example, the conductive pads CP may be provided in a pad trench formed on the second surface 100b of the substrate 100 in the pad region R2. The conductive pads CP may include a metal such as aluminum, copper, tungsten, titanium, tantalum, or an alloy thereof. The conductive pads CP may be electrically connected to an external device through a bonding wire, etc.

The second connection structure 530 may include a second through-hole conductive pattern 513, a second buried pattern 523, and a second capping pattern 533. The second through-hole conductive pattern 513 may penetrate the substrate 100 and be electrically connected to the wiring structure 1111 of the second chip S2 to be described later. In addition, the second through-hole conductive pattern 513 may extend onto the second surface 100b of the substrate 100 and be electrically connected to the conductive pads CP. A portion of the second through-hole conductive pattern 513 may cover a bottom surface and side walls of the conductive pads CP.

The second buried pattern 523 may be provided inside the second through-hole conductive pattern 513. The second through-hole conductive pattern 513 may include, for example, titanium or tungsten. The second buried pattern 523 may include a low-refractive material and may have insulating properties. The second capping pattern 533 may be provided on the second buried pattern 523.

The second chip S2 may be provided under the first chip S1. The second chip S2 may include a logic substrate 1000, logic circuits TR, wiring structures 1111 connected to the logic circuits TR, and logic interlayer insulating layers 1100. The uppermost layer of the logic interlayer insulating layers 1100 may be bonded to the wiring layer 20 of the first chip S1. The second chip S2 may be electrically connected to the first chip S1 through the first through-conductive pattern 511 and the second through-hole conductive pattern 513.

Although not shown, according to some embodiments of the inventive concept, the first connection structure 510 and the second connection structure 530 may be omitted. In this case, the first chip S1 and the second chip S2 may be electrically connected by bonding their bonding pads (not shown) to each other. The bonding pads may include at least one of, for example, tungsten (W), aluminum (Al), copper (Cu), tungsten nitride (WN), tantalum nitride (TaN), and titanium nitride (TiN).

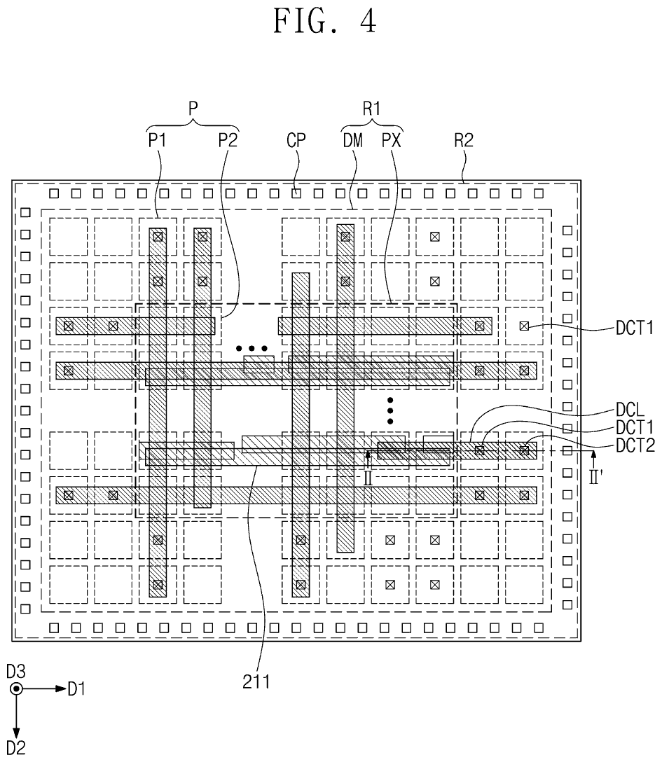

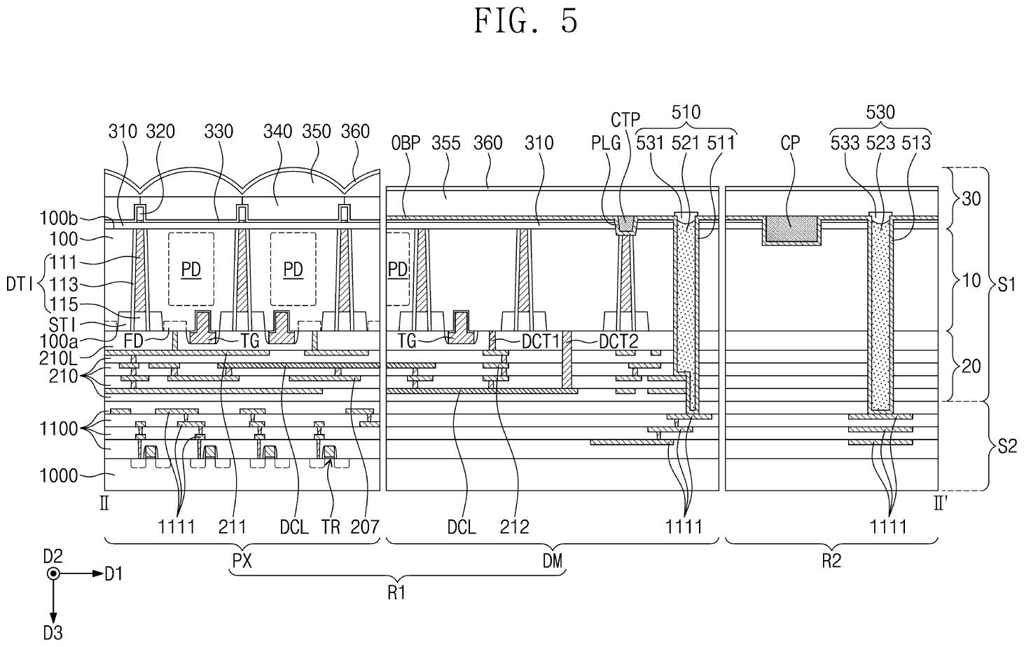

FIG. 4 is a plan view of an image sensor according to some embodiments of the inventive concept. FIG. 5 is a cross-sectional view taken along line II-II′ of FIG. 4. The description that overlaps with that described in FIGS. 1, 2, and 3 will be omitted.

Referring to FIGS. 4 and 5, a discharge line DCL on a pixel region PX may be positioned between the first wiring patterns 211 in an interlayer insulating layer 210. For example, the discharge line DCL may be provided between the first wiring patterns 211 in the third direction D3.

On the dummy region DM, a second discharge contact DCT2 may be provided on the discharge line DCL. The second discharge contact DCT2 may integrally penetrate a plurality of interlayer insulating layers 210 and 210L. The second discharge contact DCT2 and the first surface 100a of the substrate 100 may be in contact. The second discharge contact DCT2 may be provided between the device isolation portions STI in the wiring layer 20.

The wiring layer 20 of the image sensor according to an embodiment of the inventive concept may include the discharge line DCL extending from the pixel region PX to the dummy region DM and the discharge contacts DCT1 and/or DCT2 in contact with the substrate of the dummy region. In this case, among the metal wirings on the pixel region, the metal wirings that are not connected to the substrate on the pixel region may have accumulated charges due to the plasma used in the formation process. For example, charges included in a plasma used in forming second wiring patterns 207 may accumulate on the second wiring patterns 207 without being discharged to the substrate on the pixel region PX, since the second wiring patterns 207 may not be electrically connected to the substrate 100. And the amount of accumulated charges may increase in proportion to the plasma processing time. However, the accumulated charges may be discharged to the substrate on the dummy region via the discharge line DCL and the discharge contacts DCT1 and/or DCT2. The charges discharged to the substrate 100 can be dissipated through a ground region, etc. As a result, the quality of the image sensor may be improved and process defects may be reduced. Additionally, in some embodiments, the discharge line DCL may serve as a line to which a fixed voltage is applied to prevent signal interference between the second wiring patterns 207.

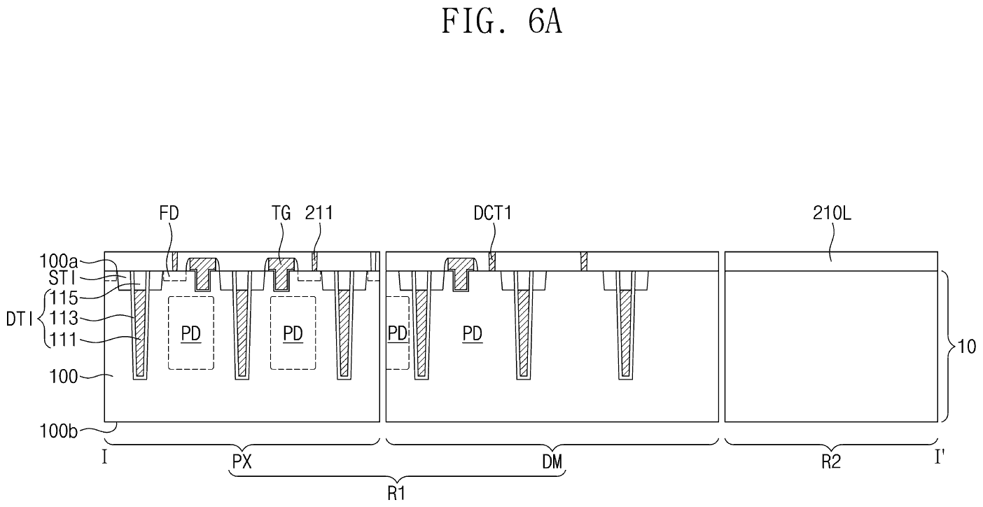

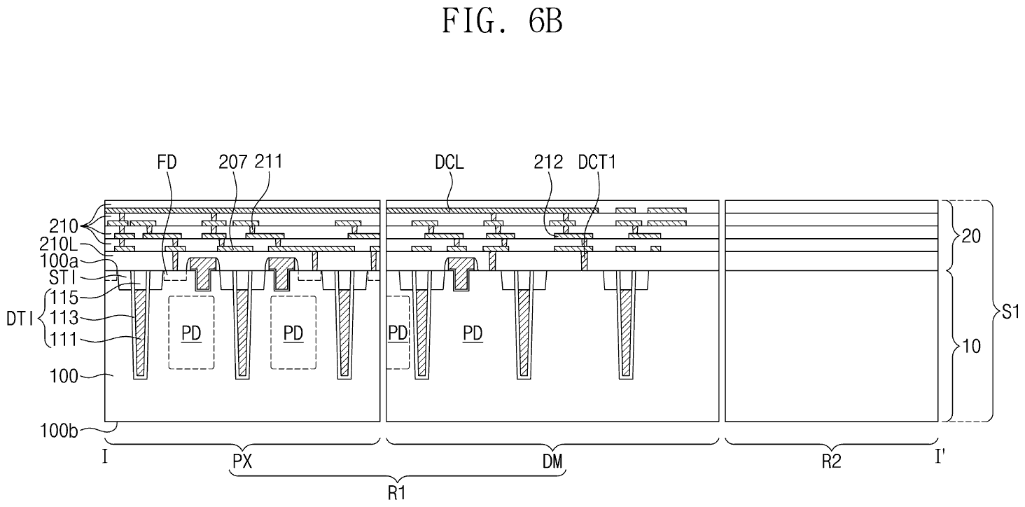

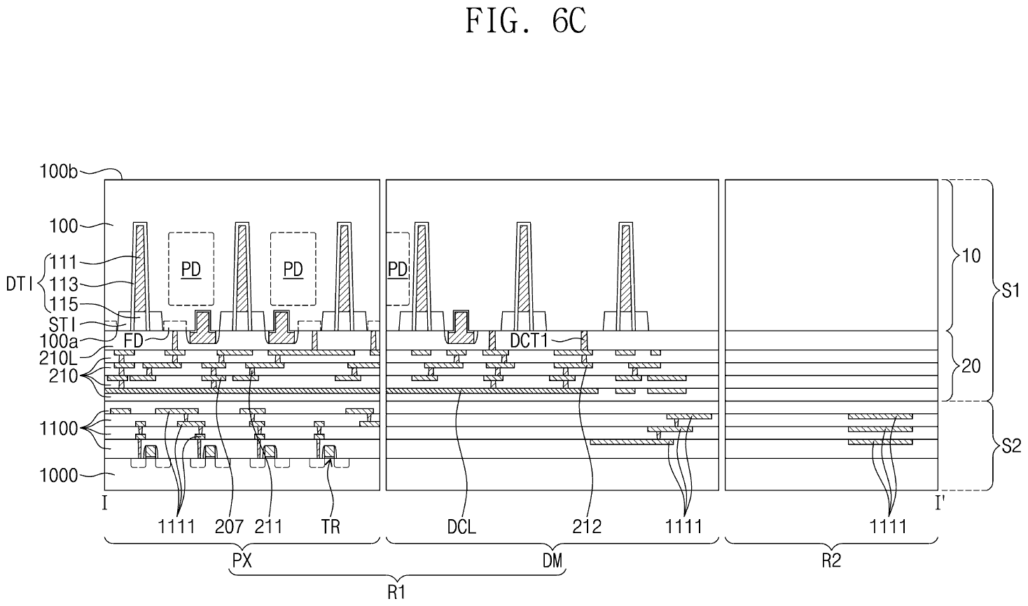

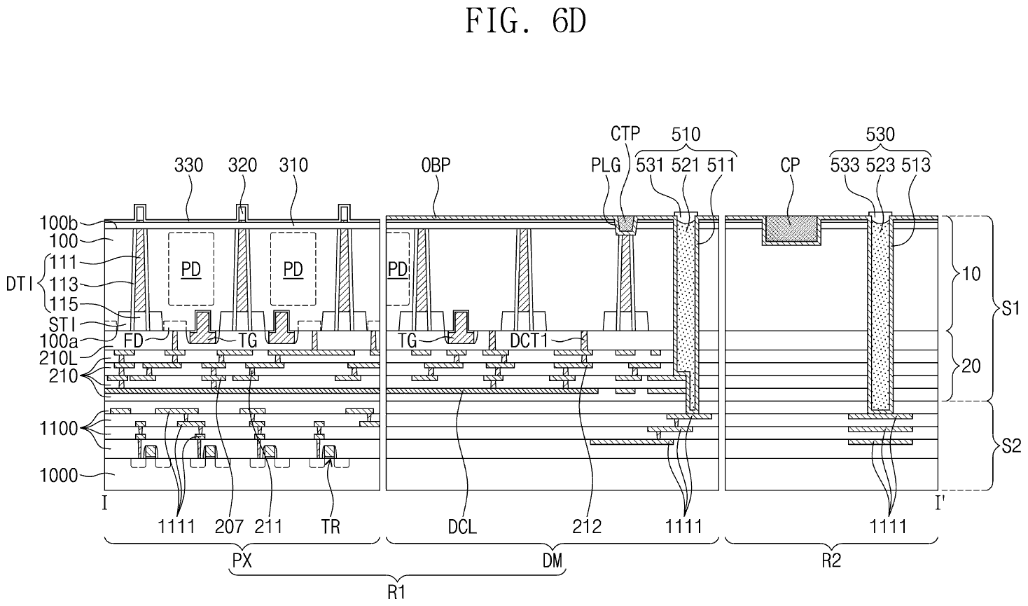

FIGS. 6A, 6B, 6C, and 6D are cross-sectional views illustrating a manufacturing process of an image sensor according to some embodiments of the inventive concept. In detail, FIGS. 6A, 6B, 6C, and 6D are cross-sectional views illustrating a manufacturing process of the image sensor illustrated in FIG. 2.

Referring to FIG. 6A, a substrate 100 including a pixel array region R1 and a pad region R2 may be prepared. The pixel array region R1 may include the pixel region PX and the dummy region DM described in FIG. 1.

The substrate 100 may have a first surface 100a and a second surface 100b facing away from each other. A device isolation portion STI may be formed on the first surface 100a of the substrate 100. The device isolation portion STI may be formed, for example, through a shallow trench isolation (STI) process.

A pixel separation portion DTI penetrating the device isolation portion STI and the substrate 100 may be formed. The pixel separation portion DTI may include a separation conductive pattern 111, a separation insulating pattern 113, and a buried insulating pattern 115. A photoelectric conversion portion PD and a floating diffusion region FD may be formed in the substrate 100 through an ion implantation process. As the photoelectric conversion portion PD and the floating diffusion region FD are formed, the photoelectric conversion layer 10 may be formed.

A transfer gate electrode TG and an upper interlayer insulating layer 210L may be formed on the first surface 100a of the substrate 100. Thereafter, first wiring patterns 211 and first discharge contacts DCT1 may be formed in the upper interlayer insulating layer 210L.

In this case, the first discharge contacts DCT1 may be formed on the dummy region DM to be in contact with the first surface 100a of the substrate 100. Forming the first discharge contact DCT1 may include etching the upper interlayer insulating layer 210L until the first surface 100a of the substrate 100 is exposed to form a contact hole and filling the inside of the contact hole with a conductive material.

Referring to FIG. 6B, a plurality of interlayer insulating layers 210 may be formed on the upper interlayer insulating layer 210L. First wiring patterns 211 and second wiring patterns 207 may be formed in the interlayer insulating layers 210 on the pixel region PX. Third wiring patterns 212 may be formed in the interlayer insulating layers 210 on the dummy region DM.

The first wiring patterns 211, the second wiring patterns 207, and the third wiring patterns 212 may be formed, for example, through a plasma-enhanced chemical vapor deposition (PE-CVD) process using plasma.

The first wiring patterns 211 may be electrically connected to the substrate 100 on the pixel region PX. The second wiring patterns 207 may not be electrically connected to the substrate 100 on the pixel region PX. As a result, the second wiring patterns 207 may be in a state where charges included in the plasma used in the formation process are accumulated without being discharged to the substrate 100 on the pixel region PX. The third wiring patterns 212 may be formed to be connected to the first discharge contact DCT1.

A discharge line DCL may be formed in the interlayer insulating layer 210. The discharge line DCL may extend from the pixel region PX to the dummy region DM. For example, the discharge line DCL may be horizontally disposed at different vertical heights (e.g., different levels in the third direction D3) in the pixel region PX and dummy region DM. In such a case, discharge line DCL may be connected through one or more connection structures (such as first connection structures 510, second connection structures 530, and/or one or more vias). The discharge line DCL may be connected to the second wiring patterns 207 in the pixel region PX. The discharge line DCL may be connected to the third wiring patterns 212 in the dummy region DM. The first wiring patterns 211, the second wiring patterns 207, the third wiring patterns 212, and the discharge line DCL in the interlayer insulating layer 210 may be formed to form a wiring layer 20 on a photoelectric conversion layer. As a result, a first chip S1 including the photoelectric conversion layer 10 and the wiring layer 20 may be formed.

Referring to FIG. 6C, a second chip S2 may be prepared. The second chip S2 may include a logic substrate 1000, logic circuits TR, wiring structures 1111 connected to the logic circuits TR, and logic interlayer insulating layers 1100.

Afterwards, the first chip S1 may be turned over and the first chip S1 and the second chip S2 may be bonded so that a logic interlayer insulating layer 1100 and the interlayer insulating layer 210 are in contact with each other. A bonding process may be performed, for example, through a thermal compression bonding process.

Referring to FIG. 6D, a grinding process may be performed until an upper surface of the pixel separation portion DTI is exposed on the second surface 100b of the substrate 100. Due to the grinding process, a thickness of the substrate 100 in the third direction D3 may be reduced.

A fixed charge layer 310 may be formed on the second surface 100b of the substrate 100. A grid 320 and a protective layer 330 on the pixel region PX, a backside contact plug PLG on the dummy region DM, an optical blocking pattern OBP, a contact pattern CTP, and a conductive pad CP on the pad region R2 may be formed. A first connection structure 510 and a second connection structure 530 may be formed on the dummy region DM and the pad region R2, respectively.

Thereafter, although not illustrated in FIG. 6D, referring to FIG. 2, a color filter 340, micro lenses 350, and a passivation layer 360 may be sequentially formed to complete an image sensor according to an embodiment of the inventive concept.

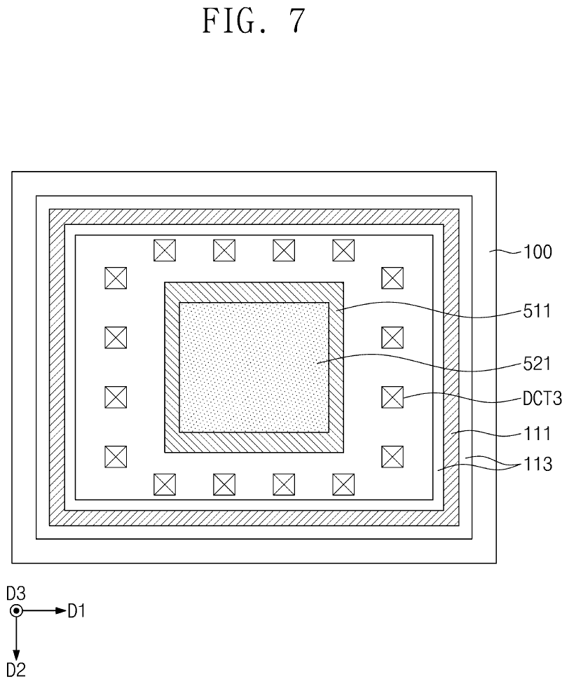

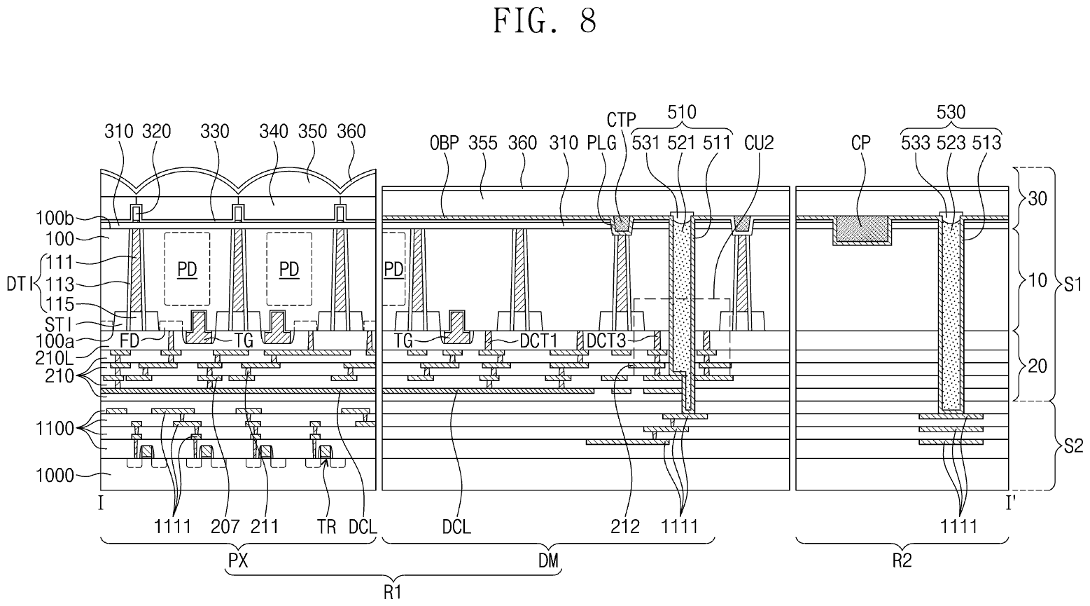

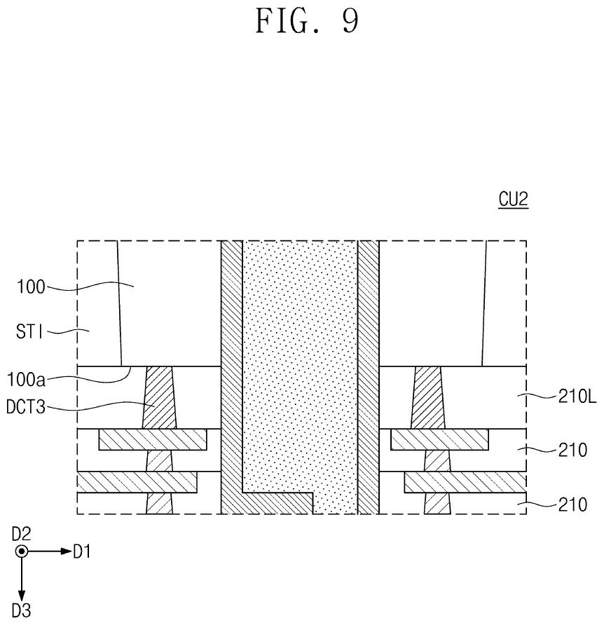

FIG. 7 is a plan view illustrating a portion of an image sensor to explain a connection structure and a discharge contact according to some embodiments of the inventive concept. FIG. 8 is a cross-sectional view of an image sensor according to some embodiments of the inventive concept. In detail, FIG. 8 is a cross-sectional view taken along line I-I′ of FIG. 1. FIG. 9 is an enlarged view of portion ‘CU2’ of FIG. 8.

To more clearly illustrate the invention, some components are omitted in FIG. 7. The descriptions that overlap with those described in FIG. 1, FIG. 2, and FIG. 3 will be omitted.

Referring to FIG. 7, FIG. 8, and FIG. 9, third discharge contacts DCT3 may be disposed adjacent to the first connection structure 510 on the dummy region DM. The third discharge contacts DCT3 may be provided in the plural (e.g., a plurality of third discharge contacts DCT3 may be provided) in the first direction D1 and/or the second direction D2. The discharge contacts DCT3 may surround the first connection structure 510 when viewed in a plan view.

The third discharge contacts DCT3 may be provided on the third wiring patterns 212. The third discharge contacts DCT3 may penetrate the upper interlayer insulating layer 210L. The third discharge contacts DCT3 may be in contact with the first surface 100a of the substrate 100. The third discharge contacts DCT3 may be provided spaced apart from the first connection structure 510 and the device isolation portion STI. A width of the third discharge contacts DCT3 may decrease as the third discharge contacts DCT3 approach the first surface 100a, as shown in FIG. 9. The third discharge contacts DCT3 may be formed through a process substantially the same as or similar to that used to form the first discharge contacts DCT1, as described in FIG. 6A.

As the third discharge contacts DCT3 are provided, charges accumulated in the metal wires adjacent to the first connection structure 510 may be discharged to the substrate 100 on the dummy region DM. As a result, quality of the image sensor may be improved and process defects may be reduced.

The wiring layer of the image sensor according to embodiments of the inventive concept may include the discharge line extending from the pixel region to the dummy region and the discharge contact be in contact with the substrate of the dummy region. In this case, some of the metal wirings on the pixel region may have the accumulated charges due to the plasma when formed. However, the accumulated charges may be discharged to the substrate on the dummy region through the discharge line and the discharge contact. As a result, the quality of the image sensor may be improved and process defects may be reduced.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the invention being indicated by the appended claims.

What is claimed is:

1. An image sensor comprising:
a substrate having first and second surfaces facing away from each other, the substrate including a photoelectric conversion portion region and a dummy region;
a photoelectric conversion portion provided in the photoelectric conversion portion region of the substrate; and
a wiring layer on the first surface,
wherein the wiring layer includes a plurality of insulating layers, a discharge line, and a discharge contact,
wherein the discharge line extends from the photoelectric conversion portion region to the dummy region in one or more of the plurality of insulating layers, and
wherein the discharge contact is in contact with the first surface on the dummy region.

2. The image sensor of claim 1, wherein the wiring layer includes an upper insulating layer in contact with the first surface among the plurality of insulating layers, and
wherein the discharge contact penetrates the upper insulating layer.

3. The image sensor of claim 1, wherein the wiring layer further includes first wiring patterns, second wiring patterns, and third wiring patterns in the plurality of insulating layers,
wherein the first wiring patterns and the second wiring patterns are provided on the photoelectric conversion portion region,
wherein the third wiring patterns are provided on the dummy region, and
wherein one or more of the first wiring patterns are electrically connected to the photoelectric conversion portion.

4. The image sensor of claim 3, wherein the second wiring patterns and the third wiring patterns are not electrically connected to the photoelectric conversion portion.

5. The image sensor of claim 3, wherein the third wiring patterns are interposed between the discharge contact and the discharge line.

6. The image sensor of claim 3, wherein the second wiring patterns are electrically connected to the discharge line.

7. The image sensor of claim 3, wherein, in the photoelectric conversion portion region, the discharge line is provided between the first wiring patterns in a direction perpendicular to the first surface of the substrate.

8. The image sensor of claim 1, wherein the discharge contact penetrates the plurality of insulating layers on the discharge line.

9. The image sensor of claim 1, wherein the discharge contact is one of a plurality of discharge contacts, and the plurality of discharge contacts are arranged in a direction in which the discharge line extends.

10. The image sensor of claim 1, further comprising a transfer gate electrode on the first surface of the substrate,
wherein the discharge contact is disposed to be spaced apart from the transfer gate electrode in a first direction parallel to the first surface of the substrate.

11. The image sensor of claim 1, further comprising device isolation portions provided on the first surface of the substrate,
wherein the discharge contact is disposed between the device isolation portions in the plurality of insulating layers.

12. An image sensor comprising:
a substrate including a photoelectric conversion portion region and a dummy region;
a photoelectric conversion portion provided in the photoelectric conversion portion region of the substrate; and
a discharge line and a discharge contact on the substrate,
wherein the discharge contact is provided on the discharge line,
wherein, when viewed in a plan view,
the dummy region surrounds the photoelectric conversion portion region,
the discharge line overlaps the photoelectric conversion portion region and the dummy region, and
the discharge contact overlaps the dummy region.

13. The image sensor of claim 12, wherein the discharge line extends from the photoelectric conversion portion region to the dummy region, and
wherein the discharge contact is one of a plurality of discharge contacts, the plurality of discharge contacts arranged in a direction in which the discharge line extends.

14. The image sensor of claim 12, further comprising wiring patterns connecting the discharge contact and the discharge line,
wherein the wiring patterns overlap the dummy region.

15. An image sensor comprising:
a substrate including a photoelectric conversion portion region, a dummy region, and a pad region, and having first and second surfaces facing away from each other;
a photoelectric conversion portion provided in the photoelectric conversion portion region of the substrate;
pixel separation portions disposed in the photoelectric conversion portion region and the dummy region in the substrate; and
a wiring layer on the first surface of the substrate,
wherein the wiring layer includes an interlayer insulating layer and a discharge line, wiring patterns, and a discharge contact in the interlayer insulating layer,
wherein the discharge line extends from the photoelectric conversion portion region to the dummy region,
wherein the wiring patterns and the discharge contact are provided on the dummy region,
wherein the wiring patterns are disposed between the discharge line and the discharge contact,
wherein the discharge contact is in contact with the first surface of the substrate, and
wherein the discharge line, the wiring patterns, and the discharge contact are electrically connected to each other.

16. The image sensor of claim 15, wherein a width of the discharge contact decreases as the discharge contact approaches the first surface of the substrate.

17. The image sensor of claim 15, further comprising device isolation portions provided on the first surface of the substrate,
wherein the discharge contact is disposed in the interlayer insulating layer between the device isolation portions.

18. The image sensor of claim 15, wherein the dummy region further includes a connection structure penetrating the substrate and the interlayer insulating layer,
wherein the connection structure comprises a conductive connection structure electrically connected to the wiring layer and to a wiring structure situated below the wiring layer, and
wherein the discharge line is spaced apart from the connection structure in a first direction parallel to the first surface of the substrate.

19. The image sensor of claim 18, further comprising a transfer gate electrode penetrating the substrate and the interlayer insulating layer,
wherein the discharge contact is spaced apart from the transfer gate electrode in the first direction.

20. The image sensor of claim 18, wherein the discharge line is one of a plurality of discharge lines, and the plurality of discharge lines are arranged in the first direction and a second direction parallel to the first surface of the substrate and perpendicular to the first direction.
